(19) United States
(12) Patent Application Publication
(10) Pub. No.: US 2009/0026513 A1
(43) Pub. Date: Jan. 29, 2009

(54) Method for forming ferroelectric thin films, the use of the method and a memory with a ferroelectric oligomer memory material

(75) Inventors: Nicklas Johansson, Rimforsa (SE); Haisheng Xu, Shanghai (CN); Geirr I. Leistad, Sandvika (NO)

Correspondence Address: BIRCH STEWART KOLASCH & BIRCH, PO BOX 747, FALLS CHURCH, VA, 22040-0747, US

(73) Assignee: Thin Film Electronics ASA, Oslo (NO)

(21) Appl. No.: 11/919,584

(22) PCT Filed: May 2, 2006
(86) PCT No.: PCT/NO2006/000162

§ 371 Date: Jan. 31, 2008

(30) Foreign Application Priority Data
May 10, 2005 (NO) 20052263

(51) Int. Cl. H01L 27/115; C23C 14/12

(52) U.S. Cl. 257/295; 427/255.6; 427/58; 257/E27.104

(57) ABSTRACT

In a method for forming ferroelectric thin films of vinylidene fluoride oligomer or vinylidene fluoride co-oligomer, oligomer material is evaporated in vacuum chamber and deposited as a thin film on a substrate which is cooled to a temperature in a range determined by process parameters and physical properties of the deposited VDF oligomer or co-oligomer thin film. In an application of the method of the invention for fabricating ferroelectric memory cells or ferroelectric memory devices, a ferroelectric memory material is provided in the form of a thin film of VDF oligomer or VDF co-oligomer located between electrode structures. A ferroelectric memory cell or ferroelectric memory device fabricated in this manner has the memory material in the form of a thin film of VDF oligomer or VDF co-oligomer provided on at least one of first and second electrode structures, such that the thin film is provided on at least one of the electrode structures or between first and second electrode structures.

The present invention concerns a method for forming ferroelectric thin films of vinylidene fluoride (VDF) oligomer or vinylidene fluoride (VDF) co-oligomer, wherein the VDF oligomer or VDF co-oligomer with another oligomer is deposited and forms a thin film on a substrate by means of evaporation, and wherein the evaporation takes place in a sealed enclosure containing the substrate and an evaporation source; the use of the method of the invention in the fabrication of ferroelectric memory cells or ferroelectric memory devices; and finally a ferroelectric memory cell or ferroelectric memory device comprising a ferroelectric memory material in the form of a thin film of VDF oligomer or VDF co-oligomer is provided between at least one of first and second electrode structures.

It is well-known that various polymers under certain circumstances display ferroelectric properties, i.e. they can be regarded as electret with dipolar properties, such that they can be switched opposite polarization directions. Ferroelectric polymers have been proposed and applied as memory materials in ferroelectric memories which exploit their polarization behaviour for binary data storage, as a ferroelectric memory cell to this end is set in one of a specific polarization state and can be switched from that one to the other. A set polarization state thus may be used to represent either a logic zero or logic one state. As a set remnant polarization in ferroelectric memory cells can be retained almost indefinitely, ferroelectric memories are very well suited to long term data storage. A well-known example of a ferroelectric polymer is polyvinylidene fluoride (PVDF) which displays a large electrical dipole moment at the vinylidene fluoride units and has several crystallization phases with different unit cell and molecular conformations. These are termed phase I or the β phase, phase II or the a phase, and phase III or the γ phase. Of these phases only I and III display ferroelectric behaviour. In case of phase I or the β phase, the large electric dipoles perpendicular to the molecular chain or c-axis of a whole crystal is arranged in a specific direction because the molecular chains have a zigzag planar structure with all-trans conformation, different from the other crystal forms. Hence PVDF in the β phase has a large spontaneous polarization which makes it particularly suitable as a ferroelectric memory material. A problem with PVDF is that the β phase only can be attained by applying mechanical forces or alternatively also electrical forces, but these methods are not easily applicable to the preparation of very thin films of PVDF, such as shall be preferred for use in ferroelectric memories. For all practical purposes PVDF could initially be used to form thick ferroelectric films by means of casting and then subjecting the cast films to mechanical stretching a number of times. However, at least since 1990 it has been found that suitable ferroelectric thin films can be obtained by synthesizing a copolymer of vinylidene fluoride (VDF) and trifluoroethylene (TrFE), commonly abbreviated as P(VDF-TrFE) The trifluoroethylene changes the dynamic kinetics of the crystallization process in such a manner that the ferroelectric film can be obtained by spin coating or casting from a solution. Moreover, P(VDF-TrFE) copolymers have the advantage that their Curie temperature, which is the temperature where they change from ferroelectric to paraelectric behaviour, always is lower than the melting point which is about 150° C. But it is a drawback that even thin films of P(VDF-TrFE) may not be suitable for use in devices fabricated with line widths less than 90 nm because spin-coated P(VDF-TrFE) thin films will not be homogenous enough. Typically, filaments form and, as can be seen by scanning electron microscopy, they can extend over about 40 to 100 nm. Also the ferroelectric domains moreover are larger than the line width of 90 nm.

A further disadvantage of P(VDF-TrFE) thin film is that the orientation of the ferroelectric domains or grain boundaries cannot be controlled in the deposition process and this results in that the P(VDF-TrFE) films has a strong tendency to imprint, as a set polarization state that has been left alone for a long time, i.e. not subjected to polarization reversal or switching, tends to become stuck in the set polarization state and hence it will be very difficult to read or rewrite an imprinted memory cell. In order to avoid the imprint phenomenon it has been proposed that the grain boundaries should be formed perpendicular to the electrode surface such that any imprint field will be perpendicular to the switching field and hence not affect the switching, i.e. operations for readout or rewrite of the memory cell. However, up to present no suitable technology for avoiding imprint has been disclosed apart from carrying out a refresh operation by switching the polarization of non-addressed ferroelectric memory cells back and forth suitably high frequency. This may, however, fatigue the memory cell and lower its useful lifetime.

As stated above, the favoured method of processing P(VDF-TrFE) copolymer in order to form a thin film is spin coating with the use of solvents. This inherently limits the complexity of the achievable structure, as solvents used in the deposition of one polymer thin-film layer may attack previously deposited layers in the deposition process. When making multilayers by means of spin coating from solution it must also be ensured that the solution used to form the new layer is able to wet the already deposited layer. This problem of wettability matching limits the choice of solvents. Another disadvantage of spin coating, i.e. global or full-surface deposition, is that deposition and patterning cannot take place in one and the same operation and provide local patterning. For several kinds of electronic devices this is a disadvantage as it is sometimes required to apply substantial in-plane patterning. An additional problem is that with P(VDF-TrFE) materials in integrated hybrid circuits with silicon-based components, the Curie temperature or low melting point of P(VDF-TrFE) poses certain restrictions on the temperatures employed in the processing. Finally, it is also a disadvantage that the copolymer P(VDF-TrFE) has a lower remanent polarization than the pure polyvinylidene fluoride. The reason for this is that trifluoroethylene monomer has a much lower dipole moment than the vinylidene fluoride monomer, and that the copolymer P(VDF-TrFE) thin film always contains amorphous, i.e. non-crystalline regions. It has been known for some years that VDF oligomer can be formed with ferroelectric crystalline phases and it has also been shown that it exhibits polarization switching. In addition the VDF oligomer has a high dipole moment which should make VDF oligomer an excellent candidate for a ferroelectric memory material, as indeed recently has been proposed in the literature. In recognition of this fact the present invention is based on an investigation of the use of ferroelectric oligomers as a memory material in ferroelectric memory devices.

Already in 1991 thin films of polyvinylidene fluoride and vinylidene fluoride oligomer were prepared by vapour deposition as disclosed in Takeno & al., “Preparation and piezoelectricity of β form poly(vinylidene fluoride) thin film by vapour deposition”, Thin Solid Films, 202, pp. 205-211 (1991). Both thin films of PVDF and the oligomer VDF were deposited by evaporation on substrate cooled to temperature below −150° C. The deposited thin-film PVDF polymer and the VDF oligomer exhibited β phase with a molecular orientation parallel to the substrate, and it was noted that the piezoelectric constant of the VDF oligomer thin film was about 50 times larger than that of PVDF.

The application of an electric field during the evaporation process was the subject of a paper by Noda & al., “Structures of vinylidene fluoride oligomer thin films on alkali halide substrate”, Journal of Applied Physics, Vol. 86, No. 7, pp. 3688-3693 (1999) which discloses that VDF oligomer evaporated in vacuum onto KCl (001) substrates kept at temperature from room temperature to 90° C., formed with non-polar a phase at temperatures below 50° C., but a phase transformation from this phase to the polar P phase could be induced by raising the temperature of the substrate from 50° C. to 80° C. It was suggested that the molecular chain of VDF oligomers align their c-axes along the (110) row of K⁺ or Cl⁻ with the aid of electrostatic interaction under enough thermal movement.

Molecular orientation has moreover been substantiated in a paper by Oshida & al., “Effect of substrate temperature on molecular orientation in evaporated thin films of vinylidene fluoride oligomer”, Japanese Journal of Applied Physics, Vol. 36, pp. 7389-7394 (1997). Thin films of VDF oligomer were obtained with high crystallinity by evaporation in vacuum. It was observed that the molecular orientation changes from perpendicular to parallel to the substrate at substrate temperatures between −30° C. and −50° C., and the stable crystal structure was then Phase II, i.e. the α phase, which is the non-ferroelectric crystal form. In the paper by Noda & al., “Structures and Ferroelectric Natures of Epitaxially Grown Vinylidene Fluoride Oligomer Thin Films”, Japanese Journal of Applied Physics, Vol. 39, pp. 6358-6363, part 1, No. 11, (November 2000), the ferroelectric characteristics of VDF oligomer thin films were revealed for first time. It was found that 37 nm thick thin films of epitaxially grown VDF oligomer thin films on a KBr substrate showed a coercive field of about 200 MV/m, and the polarization reversal in VDF oligomer thin film was confirmed both by piezoresponse images and hysteresis curves. It should be noted that the estimated coercive field of about 200 MV/m is much larger than that of the polymer polyvinylidene fluoride. This study was also a clear indication that a thin film of VDF oligomer may possess ferroelectric functionality on a molecular scale and hence could be a candidate for new electronic materials, for instance in high density molecular memories and other nanoscale devices.

In the paper “Molecular Ferroelectricity of Vinylidene Fluoride Oligomer Investigated by Atomic Force Microscopy”, Japanese Journal of Applied Physics, Vol. 4 (2001), pp. 4361-4364, Part 1, No. 6B (June 2001), Noda & al. further investigated the nanometer-scale electric properties of local ferroelectric domains formed in thin films of VDF oligomer. Local poling and the observation of the piezoelectric response revealed that polarized domains were reversibly formed and erased in a nanometer-thick VDF oligomer thin film by applying DC or pulse voltages between the conductive AFM tip and a bottom electrode. A local ferroelectric domain of 65 nm was created and the authors suggested that VDF oligomer could be a promising candidate for ferroelectric applications such as i.a. high density data storage devices. Also in a paper of 2002, “Polarization Reversal in Vinylidene Fluoride Oligomer Evaporated Films”, Polymer Preprints Japan, Vol. 51, No. 12, Noda & al. published hysteresis curves of 500 nm thick VDF oligomer films measured at frequencies of 15 MHz and 800 Hz respectively. The maximum polarization of the electric displacement was found to lie in the range between ±150 mC/m² and the coercive field varied from about 120 V in the former case more than 150 V in the latter case, which showed a much more square hysteresis curve. Further, Noda & al., “Investigation of Ferroelectric Properties of Vinylidene Fluoride Oligomer Evaporated Films”, Material Research Society Symp. Proceedings, Vol. 748 (2003), disclosed investigations of vinylidene fluoride oligomer films evaporated onto various substrates at temperatures about the temperature of liquid nitrogen. It was shown that the VDF oligomer films were mainly formed in the ferroelectric phase, i.e. crystallizing in form I or the D phase, and that the molecular chains were oriented parallel to the substrate surfaces regardless of the substrate material and the thickness of the VDF oligomer film. The ferroelectric properties and behaviour were verified experimentally and a polarization for 500 nm thick film was found to be in the order of 250 mC/m² with a coercive voltage in the order of 60 V. At the coercive voltage the current response was in the order of 75 nA. In other words, this paper confirmed the early findings about ferroelectric thin films with a remanent polarization about 250 mC/m² and a coercive field strength somewhat higher than 100 MV/m.

In Matsushige & Yamada, “Ferroelectric Molecular Films with Nanoscopic High-Density Memories”, Annals of the New York Academy of Sciences 960 pp.-1-5 (2002), the formation and visualization of nanometer scale polarization domains in ultra-thin ferroelectric molecular films was described both for PVDF and PVDF copolymer as well as vinylidene fluoride (VDF) oligomer. Evaporation was used for forming the thin films of VDF oligomer and polarization switching behaviour was claimed for these films. Matsushige & Yamada concluded that VDF oligomer in this polar form has the potential for realizing ferroelectricity on a molecular scale and hence could be considered a candidate for memory materials in i.a. high-density molecular memories. Specific quantified results of VDF oligomer were, however, not given in this paper.

Noda & al., “Remanent polarization of evaporated films of vinylidene fluoride oligomers”, Journal of Applied Physics, Vol. 93, No. 5, pp. 2866-2870 (2003) disclosed that a remanent polarization of 130±3 mC/m² and rectangular D-E hysteresis curves were realized in a synthesized vinylidene fluoride oligomer [CF₃(CH₂CF₂)₁₇] film evaporated onto a platinum surface around the temperature of liquid nitrogen. The results suggested that vinylidene oligomer thin film has an extremely high crystallinity and the electrical dipoles are arranged almost perpendicular to the film surface. The coercive field, which is larger than that of ferroelectric polymers, was attributed to steric hindrance arising from iodine atoms at VDF oligomer chains.

The above-mentioned prior art publications give a clear indication that VDF oligomer may be a promising candidate for ferroelectric memory materials. But, as it has turned out, the above-cited prior art provides no clear directions for a successful fabrication of ferroelectric memory materials that would allow the implementation of commercially viable ferroelectric memories, although the published research results indicate the formation of nanoscale ferroelectric domains and ferroelectric properties with regard to remanent fields and current outputs might make the VDF oligomer per se as a promising candidate material for ferroelectric memories. This, however, would ultimately hinge on whether a suitable processing method can be developed.

A proposal to this end is disclosed by Japanese Patent Application 2002239437, published as JP2004076108 (Noda & al.). The objective set in this application is to provide a ferroelectric thin film with good ferroelectric properties and which can be fabricated with few restrictions. A vinylidene fluoride oligomer thin film is formed by vapour depositing or VDF oligomer on a substrate in vacuum or in a dry gas while the substrate is kept at −130° C. or lower. This is basically implied with what can be deduced from the above-cited prior art, but there is no indication of the quality of the thus deposited ferroelectric thin films apart from their manifest ferroelectric behaviour.

Although the above-cited research publications which to some extent can be regarded as prior art of the present invention, point to the possibility of making oligomer thin films for use as a ferroelectric memory material in ferroelectric memories and moreover have proved the ferroelectric nature of VDF oligomer including polarization switching and a high remanent polarization, these findings have mainly been based on fairly thick films, namely with a thickness around 500 nm. For thinner films almost no data have been available and the cited research literature, which although providing a clear recommendation for use of VDF oligomer films in high density ferroelectric memories, gives no clear indication how high-quality ultra-thin VDF oligomer films with a desired ferroelectric property can be made in a manner that makes them suitable for application as memory material in high-density ferroelectric memories or with line widths in the range below 100 nm. Neither does the cited research literature address the problem of process steps and parameters that would serve to ensure the formation of high-quality ultra-thin VDF oligomer films, while at the same time avoiding circumstances and conditions that will be detrimental to the quality of the films and make them unsuitable for use as a memory material. As mentioned above, the copolymer P(VDF-TrFE) has proved particularly suited as a memory material. By a not at all hard-pressed analogy the same might be expected of ferroelectric co-oligomers, but there are no data on these in the literature and no hints for their application.

Hence a first object of the present invention is to provide a method for making ultra-thin VDF oligomer or VDF co-oligomer ferroelectric films to allow the exploitation thereof to its fullest extent as memory material in high-density ferroelectric memories. In that connection it is particularly desired that ferroelectric VDF oligomers or VDF co-oligomers shall enable the realization of matrix-addressable ferroelectric memories with line width below the 0.1 μm and comparable small pitches.

A second object of the present invention is to provide a method whereby external and environmental factors in the deposition process are controlled so as to avoid deterioration in the quality of the films deposited due to such factors.

A third object of the present invention is to provide the use of the method according to the method of the invention in the fabrication of ferroelectric memory cells or ferroelectric memory devices.

Finally, a fourth object of the present invention is to provide a ferroelectric memory cell or ferroelectric memory device with a minimum of topological restrictions and wherein the memory material is a ferroelectric oligomer or co-oligomer provided by means of the inventive method.

The above objects as well as further features and advantages are achieved according to the invention with a method which is characterized by steps for evacuating the sealed enclosure to a pressure below 1 mbar, cooling the substrate to a temperature in the range where a major fraction of the oligomer or co-oligomer crystallizes in a polar crystalline phase and oriented parallel to the substrate, but not below a temperature at which the saturation vapour pressure of water in the enclosure becomes equal to the partial pressure of water vapour before the cooling starts, and in any case not below −130° C., evaporating the oligomer or co-oligomer onto the substrate to form a thin film with a predetermined thickness, increasing the temperature of the substrate to room temperature after the deposited oligomer or co-oligomer thin film has reached the predetermined thickness, and heating the deposited thin film of oligomer or co-oligomer to a temperature in the range 50° C. to 150° C. in order to anneal the deposited thin film, whereby a residual non-polar crystalline phase is converted to a polar crystalline phase; as well as with the use of the method of the invention wherein the ferroelectric material is provided in the form of a thin film of VDF oligomer or a VDF co-oligomer located between one or more of first and second electrode structures; and finally, with a ferroelectric memory cell or ferroelectric memory device which is characterized in that the thin film of VDF oligomer or VDF co-oligomer provided wholly in its polar crystalline phase without defects and with a parallel orientation of to the surface thereof on at least one of the electrode structures, or between the first and second electrode structures of said at least one of first and second electrode structure.

Further features and advantages of the present invention will be apparent from the appended dependent claims.

The present invention shall now be explained in more detail in connection with a brief elucidation of the general background of the invention and with exemplary embodiments in regard of the method according to the invention, its use in the fabrication of ferroelectric memory cells or devices and as well in conjunction with examples of ferroelectric memory cells or ferroelectric memory devices which has been made with the method according to the present invention, taken in conjunction with the appended drawing figures, of which

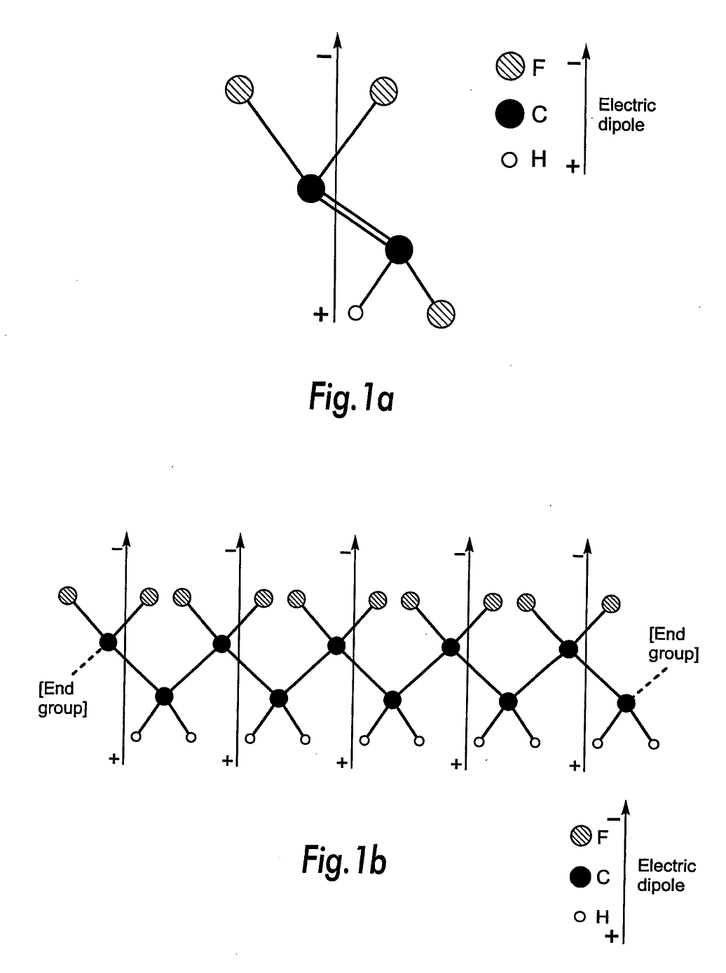

FIG. 1a shows the structure of a VDF monomer,

FIG. 1b the structure of a five-unit VDF oligomer,

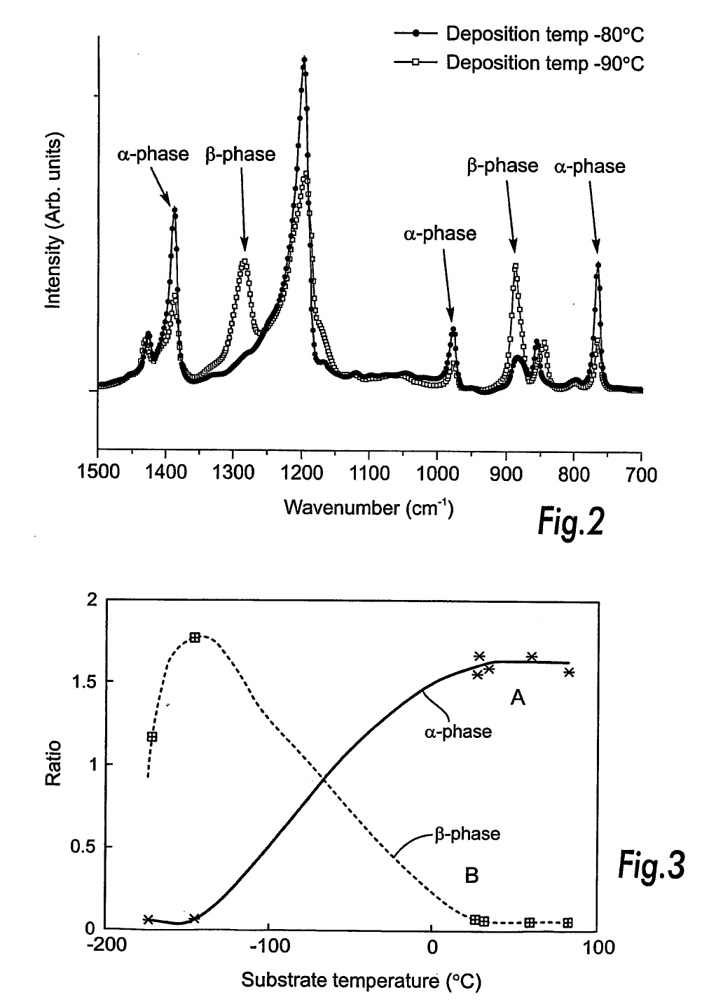

FIG. 2 FTIR spectra of VDF oligomer film deposited with the method according to the invention and at different deposition temperatures,

FIG. 3 the spectral ratios of non-polar a phase and polar β phase as function of substrate temperature, referred to their IR spectral bands,

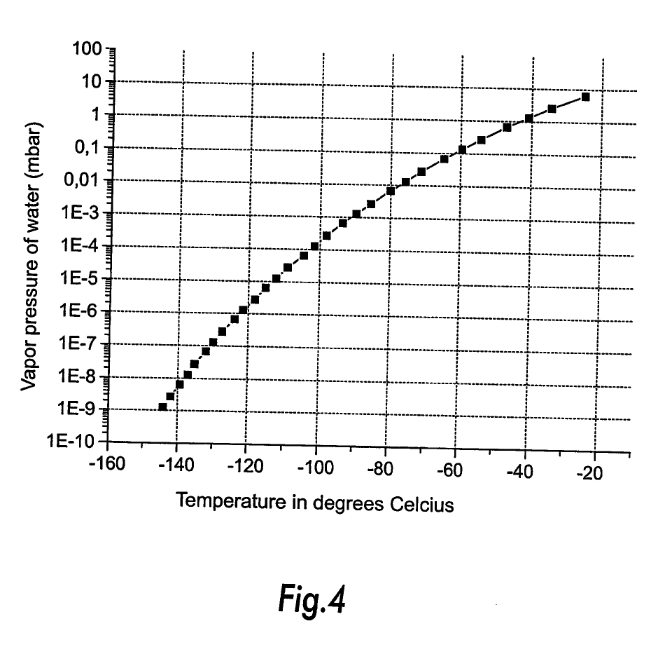

FIG. 4 the vapour pressure of water as a function of temperature,

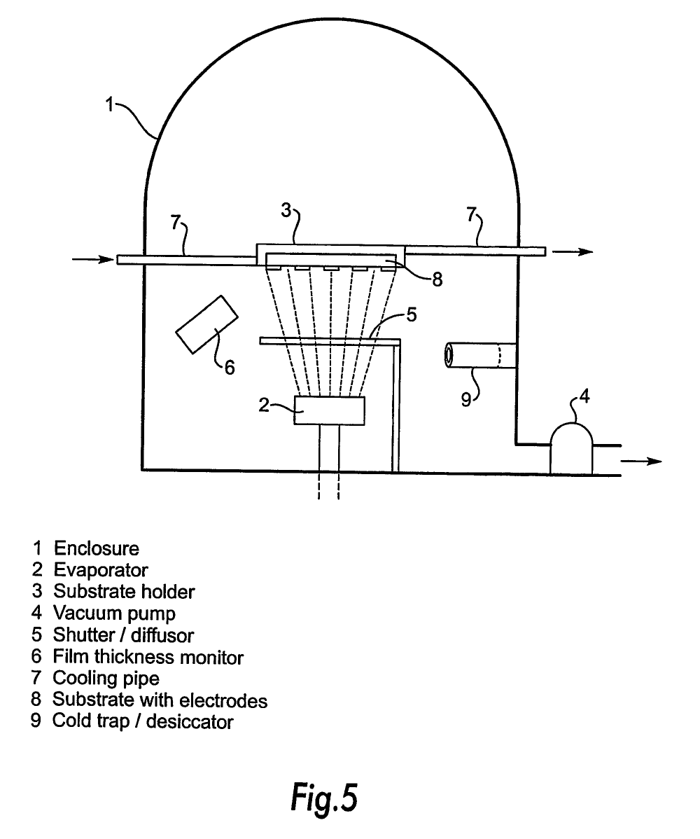

FIG. 5 a section through an evaporator apparatus as used in the present invention,

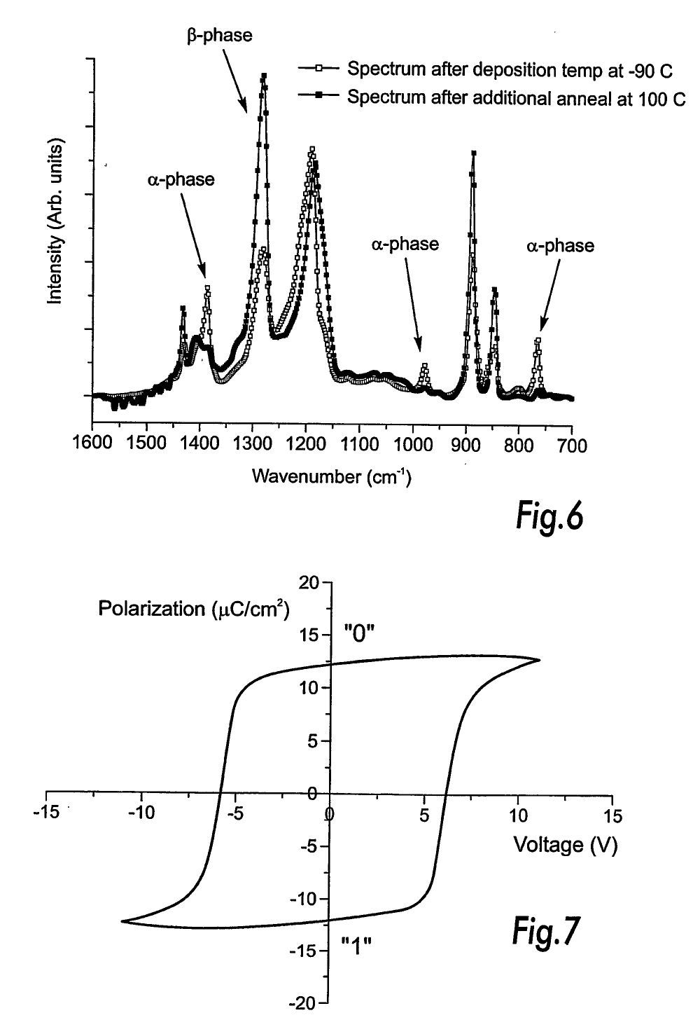

FIG. 6 FTIR spectra of VDF oligomer film deposited at −90° C. before and after annealing step as used in the method according to the present invention,

FIG. 7 the hysteresis curve of a 600 Å thick VDF oligomer film with Au electrode and deposited with the method according to the present invention,

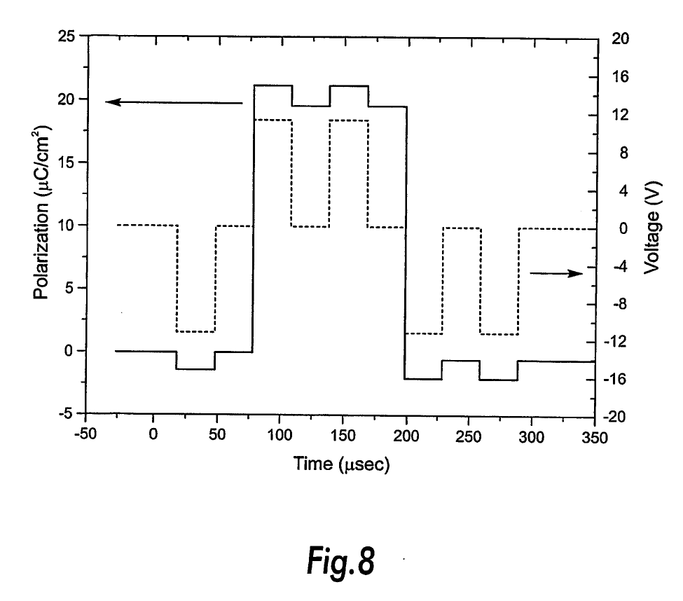

FIG. 8 a so-called PUND measurement of a ferroelectric VDF oligomer as deposited with the method according to the present invention,

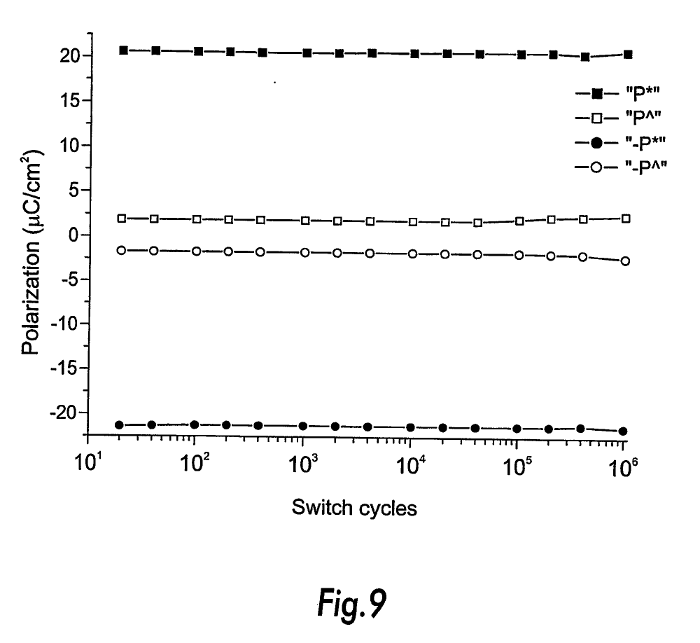

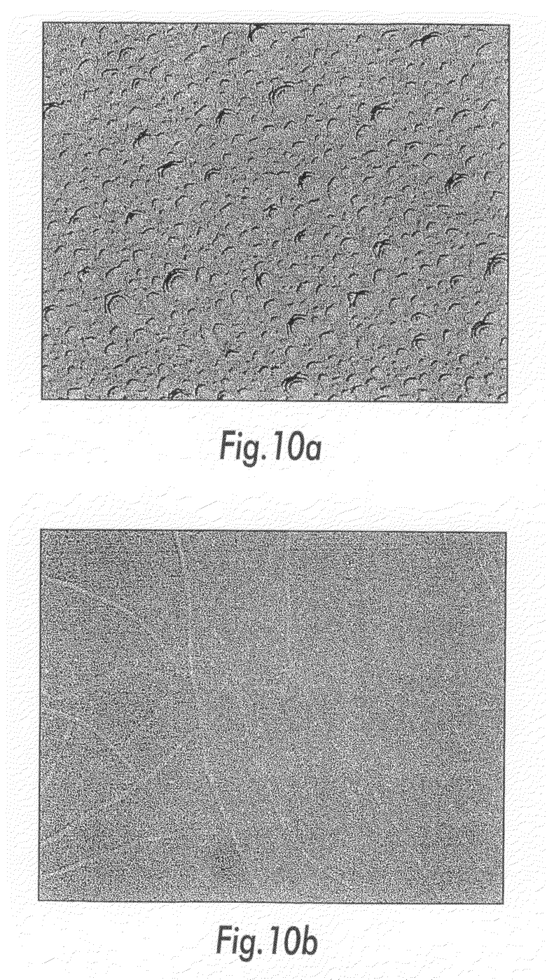

FIG. 9 fatigue curves of a VDF oligomer film deposited with the method according to the present invention and in memory cell with gold electrodes,

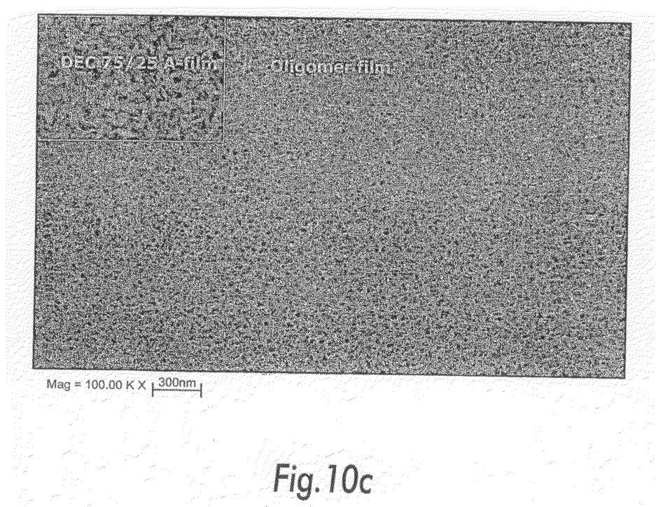

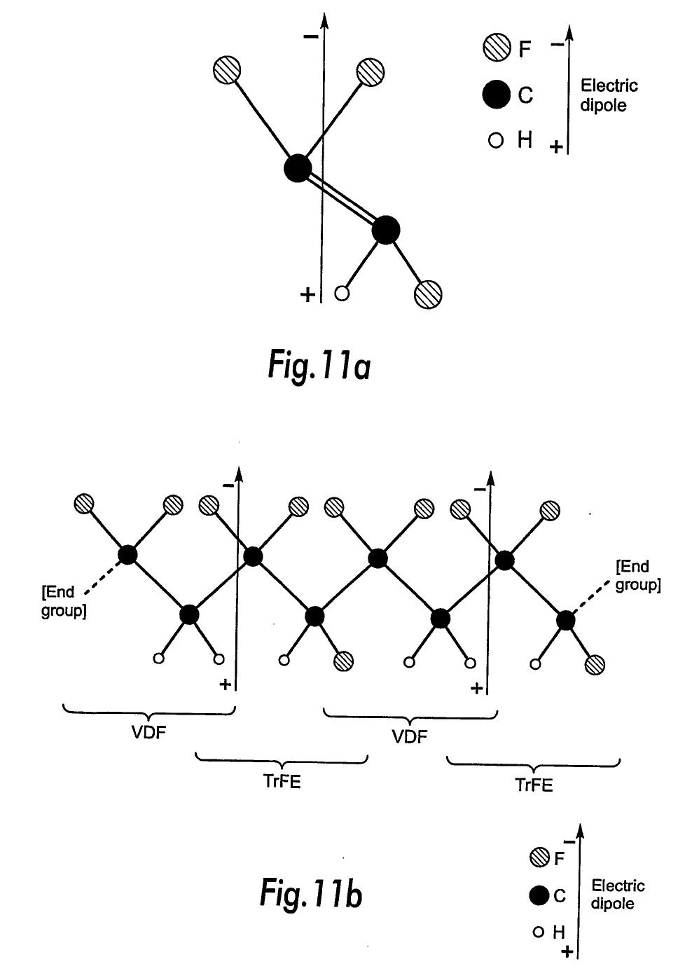

FIG. 10a defects in the form of bubbles in a VDF oligomer film deposited under non-optimal conditions,

FIG. 10b crack formation in a VDF oligomer film deposited under non-optimal condition,

FIG. 10c a VDF oligomer film deposited with the method according to the present invention,

FIG. 11a the structure of a TrFE monomer,

FIG. 11b structure of a two-unit VDF-TrFE co-oligomer,

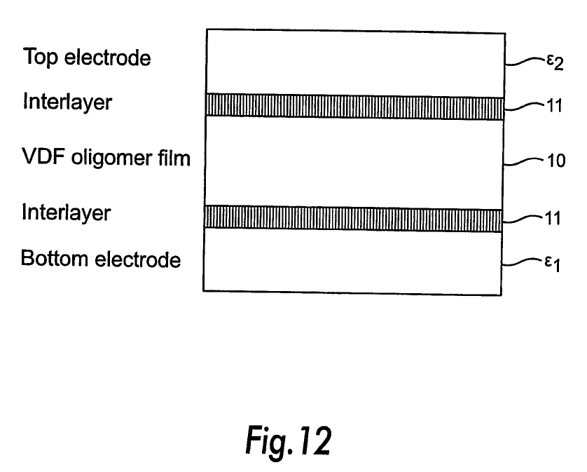

FIG. 12 a cross section through a three-dimensional electrode structure with a conformal layer of oligomer or co-oligomer deposited with a method according to the present invention,

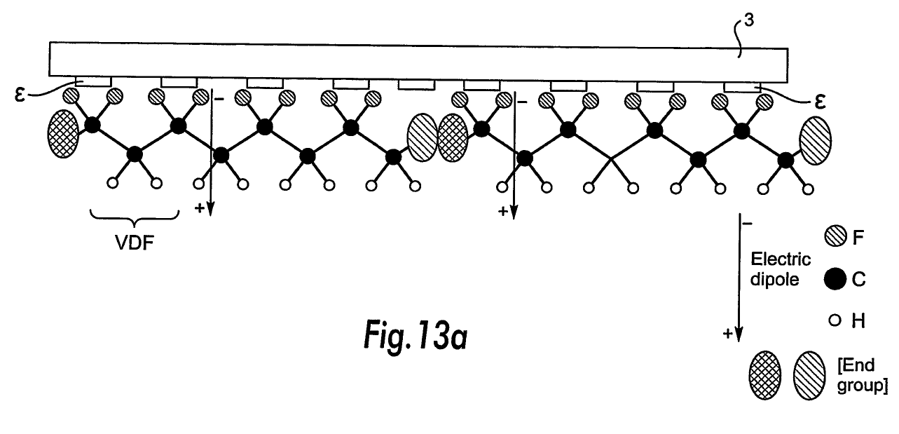

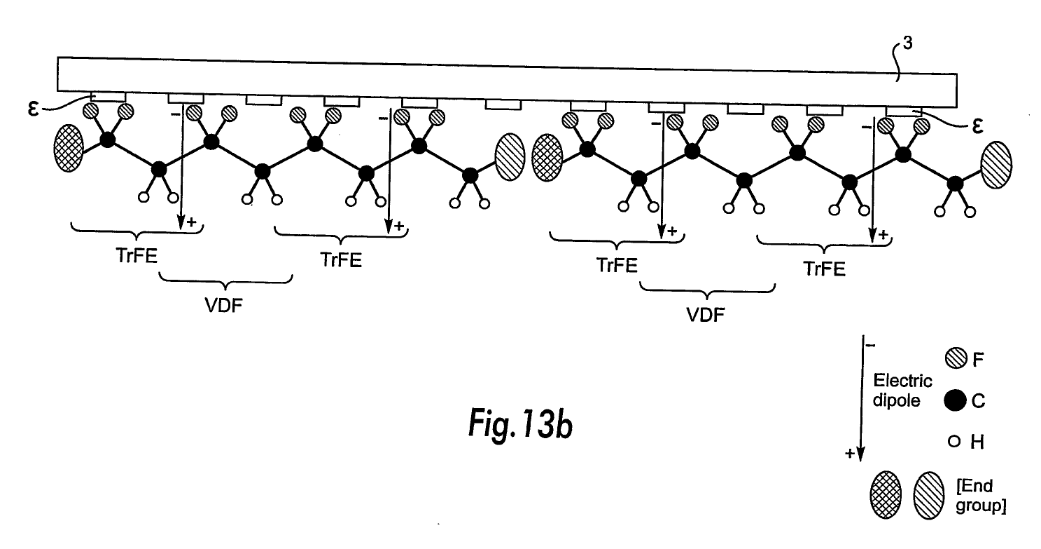

FIG. 13a the structure and orientation of VDF oligomer as deposited with the method according to the present invention,

FIG. 13b the structure and orientation of VDF-TrFE co-oligomer as deposited with the method according to the present invention,

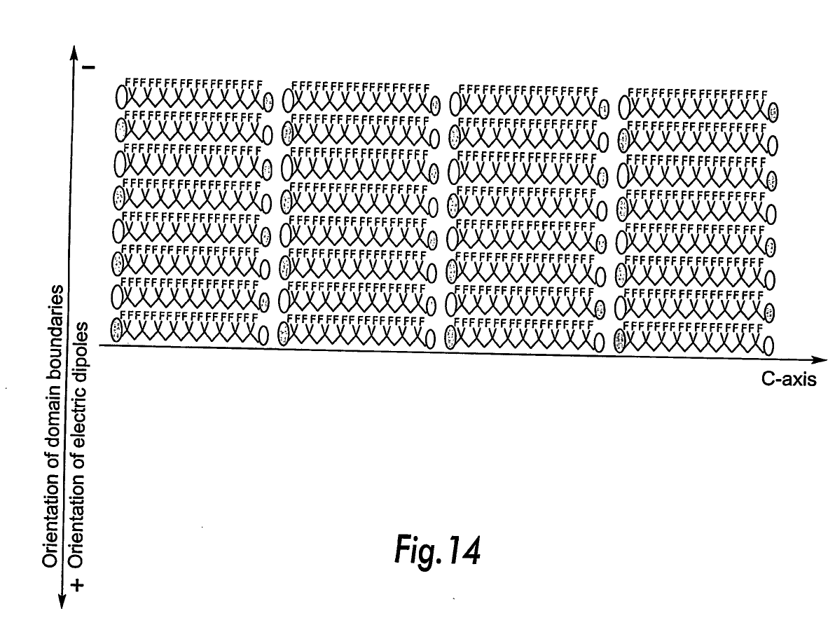

FIG. 14 the orientation and ordering of VDF oligomer crystals in the layers deposited with the method according to the present invention,

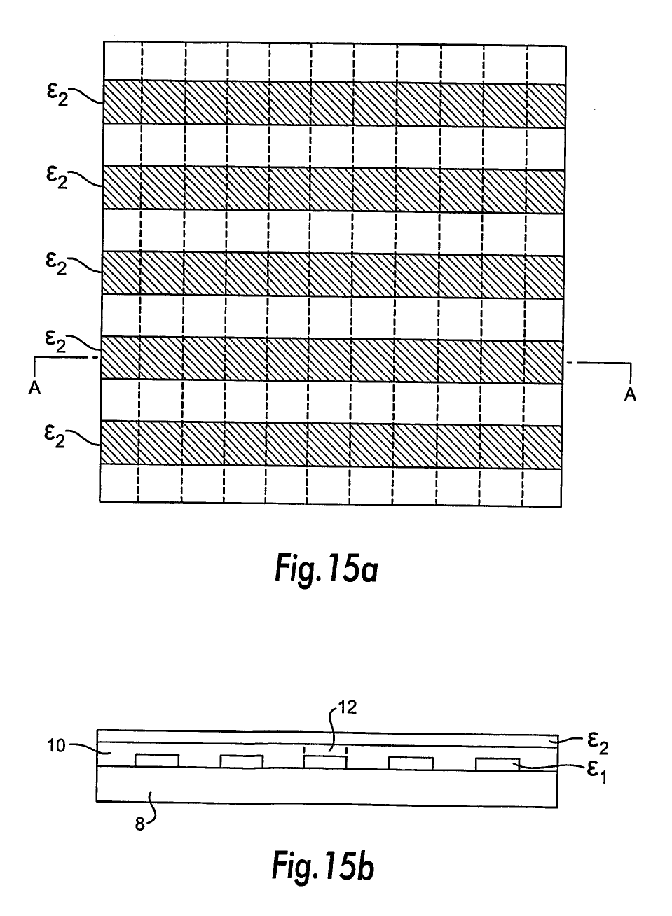

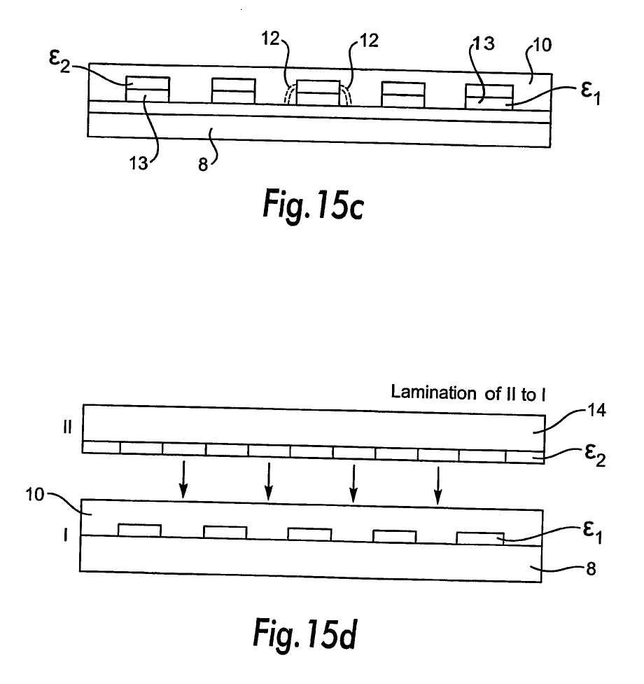

FIG. 15a plan view of a passive matrix-addressable ferroelectric memory,

FIG. 15b a cross section through the memory device in FIG. 15a, taken along the line A-A,

FIG. 15c a cross section through a passive matrix-addressable memory similar to the one in FIG. 15a, but with a different arrangement of electrodes and memory material,

FIG. 15d schematically and in cross section the joining of two component parts of a passive matrix-addressable ferroelectric memory,

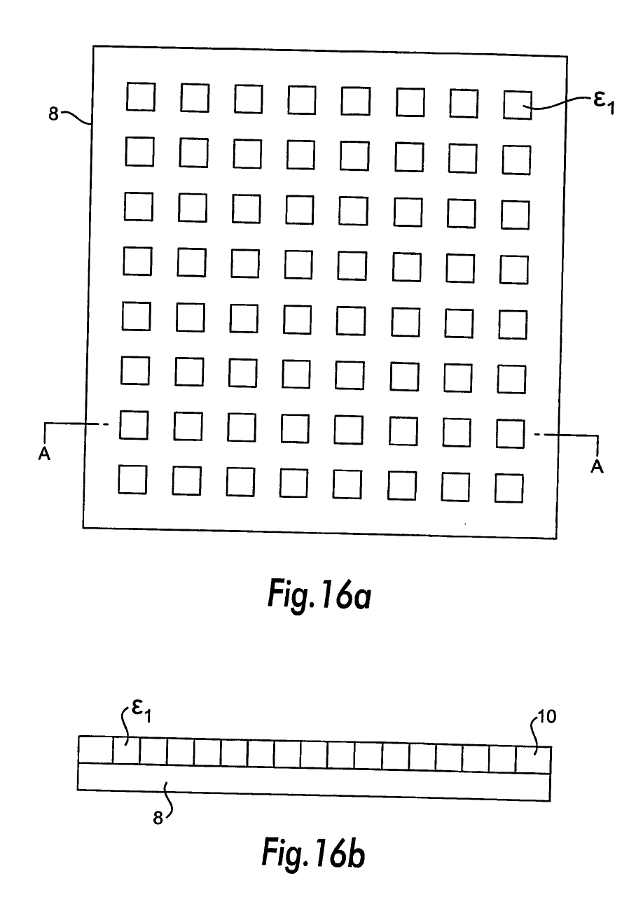

FIG. 16a a plan view of a matrix-addressable ferroelectric memory with pillar-like electrodes and memory cell arranged laterally between the electrodes,

FIG. 16b a cross section through the memory device in FIG. 16a,

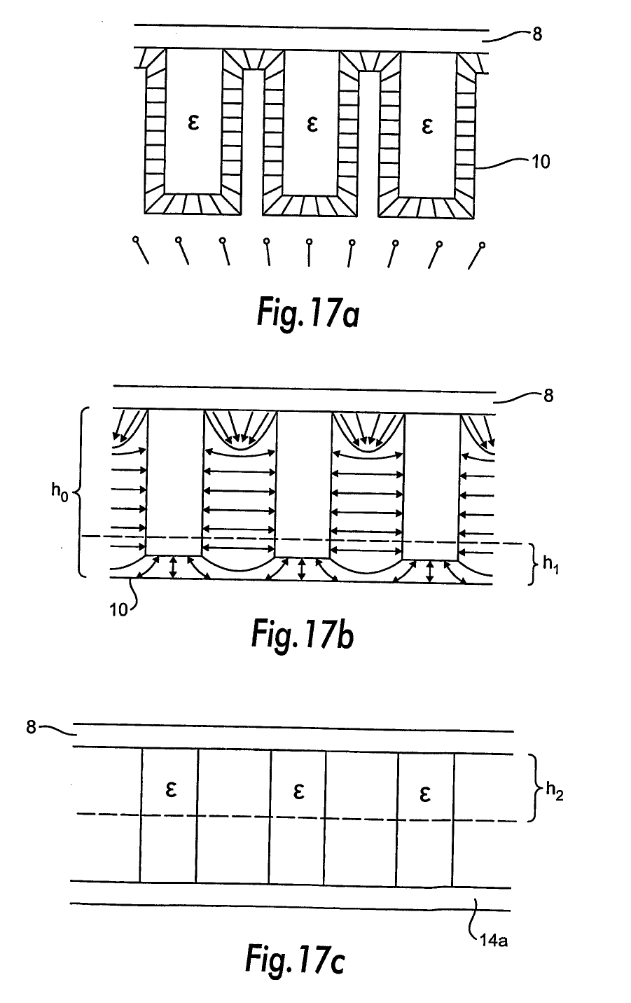

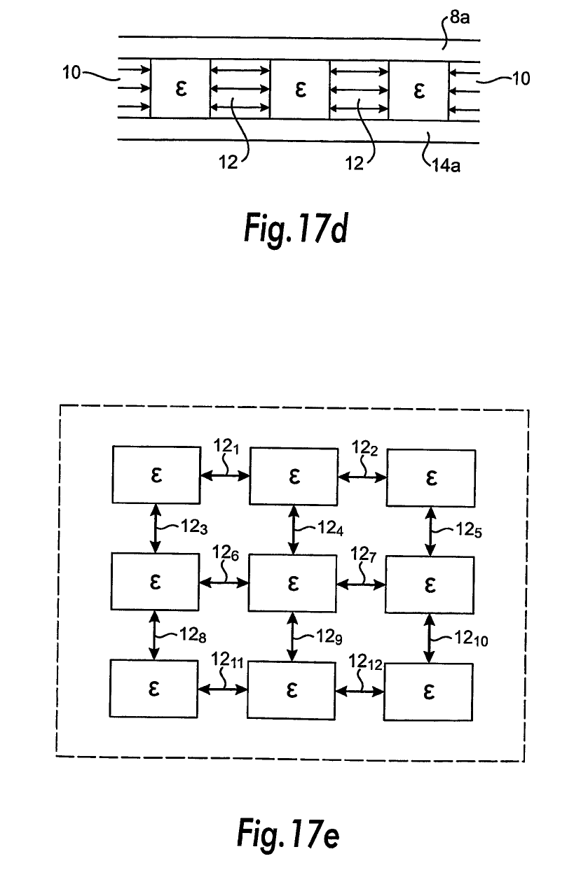

FIG. 17a a cross section through a set of pillar-like electrodes with a growing layer of a VDF oligomer or co-oligomer deposited with the method according to the present invention with the dipoles indicated,

FIG. 17b a cross section through the same electrode set as in FIG. 17a after completed deposition, with the electric dipoles indicated,

FIG. 17c a step in the fabrication of the memory device in FIG. 16a and with the pillar-like electrodes,

FIG. 17d a following step in the fabrication of the memory device in FIG. 16a, and

FIG. 17e a plan view of the arrangement of pillar-like electrodes in the memory device in FIG. 16a, with lateral memory cells as defined in the memory material between the former.

In order to ease the understanding of the present invention before any specific embodiments thereof are disclosed, a discussion of the general background of the present invention will be given.

As mentioned in the introduction of the application, it was discovered in 1991 that VDF oligomers can be used to form thin films crystallized directly in crystallination in the α phase, i.e. the paraelectric phase, by controlling the deposition temperature and deposition rate. This led to a quite extensive research, particularly in Japan, on the fundamental as well as electrical properties of VDF oligomer thin films, but it was not until quite recently, namely in 2001, that Noda & al. found that VDF oligomer exhibited the dipolar polarization behaviour and hysteresis as well as polarization reversal which are necessary requirements for its application in ferroelectric memories. However, up to now no specific results on the ferroelectric properties of ultra-thin oligomer films, in particular of VDF oligomer have been disclosed, although atomic force microscopy has been used to locally probe the films and detect ferroelectric domains in the submicron range and also for effecting a polarization reversal. Published research results for fairly thick VDF oligomer films, i.e. with a thickness of about 500 nm, have been disclosed, showing a well-defined hysteresis curve with a large remanent polarization in the order of 13 mC/cm² and a coercive field in the order of 120 MV/m. By using atomic force microscopy it has been possible to locally probe ultra-thin VDF oligomer films and detect ferroelectric domains therein as well as effecting a reversal of the polarization. For ultra-thin films, no electrical data in the form of a measured hysteresis curve or so-called PUND measurements, a standard pulse sequence used to probe ferroelectric materials comprising a negative preset pulse followed by 2 positive pulses and 2 negative pulses, have been published. The lack of such data on ultra-thin films of ferroelectric oligomer is presumably related to the inability to make such films with the required quality, e.g. with an absence of defects that adversely may effect its ferroelectric behaviour. However, research carried out by the present applicant in order to arrive at a suitable method for fabricating ultra-thin VDF oligomer or co-oligomer ferroelectric films generally has yielded high-quality films and measurement results in regard of hysteresis curves and fatigue curves which indicate that the method according to the present invention is able to realize the above-stated objects of the present invention, of which more will be said at the end of the description.

In order to be able to apply ultra-thin VDF oligomer films as memory material in ferroelectric thin-film memories the requirements in terms of quality is fairly similar to those also set for PVDF or P(VDF-TrFE) memory films. In particular it is necessary to avoid cracks and pinholes in the films, defects that may lead to short circuit when a top metal electrode is deposited on the already deposited memory material. It cannot be seen that this problem has been addressed at the all in the published research cited above as prior art. Hence the work of the present applicant has been directed to implementation of the method according to the invention for fabricating on an industrial scale, and this implies that the quality of the deposited oligomer thin films must be maintained over large areas and at least be able to cover a four-inch wafer. Also in this context and to meet the requirements of the process economy for industrial application, the deposition time cannot be too long. In the above-cited research publications, particularly the papers by Noda & al., “Structure and Ferroelectric Natures of Epitaxially Grown Vinylidene Fluoride Oligomer Thin Films”, Japanese Journal of Applied Physics, Vol. 39, pp. 6358-6363, part 1, No. 11 (November 2000); “Molecular Ferroelectricity of Vinylidene Fluoride Oligomer Investigated by Atomic Force Microscopy”, Japanese Journal of Applied Physics, Vol. 4 (2001), pp. 4361-4364, Part 1, No. 6B (June 2001); “Polarization Reversal in Vinylidene Fluoride Oligomer Evaporated Films”, Polymer Preprints Japan, Vol. 51, No. 12 (2002); “Investigation of Ferroelectric Properties of Vinylidene Fluoride Oligomer Evaporated Films”, Material Research Society Symp. Proceedings, Vol. 748 (2003); and Matsushige & Yamada, “Ferroelectric Molecular Films with Nanoscopic High-Density Memories”, Annals of the New York Academy of Sciences 960, pp. 1-15 (2002); and finally, in Noda & al., “Pyroelectricity of Ferroelectric Vinylidene Fluoride Oligomer-Evaporated Thin Films”, Japanese journal of Applied Physics, Vol. 42 (2003), pp. 1334-1336, November 2003 disclosing or indicating polarization results, there are two parameters that stand out prominently with regard to the processing time of each substrate or wafer. The first is the deposition rate which lies in the range of 2-4 Å/min, and this means that even for a 500 Å thick VDF oligomer film as a goal that would meet an object of the present invention, the deposition time will be in the order of 125-250 min. A second parameter which increases the turn-around time for each oligomer-coated wafer, is the time required to heat the wafer from the very low substrate temperature at deposition and up to room temperature. All prior art indicates that after the deposition of VDF oligomer film, the wafer must be heated very slowly to ambient temperature in the vacuum. However, there is no indication what this implies in term of actual time consumption, but the present applicant has found that in regard of a total cycle time a heating rate of 3° K./min must be considered the minimum but it could advantageously be much larger.

The present invention particularly concerns a method for forming ferroelectric thin films as a memory material in ferroelectric thin-film memories, using either vinylidene fluoride oligomer (VDF oligomer) or vinylidene fluoride co-oligomer (VDF co-oligomer). The vinylidene monomer generally is a unit with the formula —H₂CCX₂ where X usually is a chloride, fluoride or cyanide radical, a compound termed a vinylidene resin. The vinylidene itself is based on the vinyl group CH₂═CH— which is derived by removing one hydrogen atom from ethylene. In other words vinylidene fluoride is simply a vinylidene resin with two fluorine atoms. The VDF oligomer is formed by a limited numbers of such units chained together and has as mentioned been shown to be ferroelectric, i.e. possessing a polar crystalline phase when formed under specific conditions.

FIG. 1a shows the structure of a VDF monomer. The two hydrogen atoms are bonded to a first carbon atom which forms a double bond to a second carbon atom. Two fluorine molecules are bonded to the latter. FIG. 1b shows the structure of a VDF oligomer, here rendered as a chain of 5 VDF monomers, but without showing specific end groups. The carbon atoms of the VDF molecule bond to their neighbour carbon atoms and form the backbone of the oligomer chain, which is attached to selected end groups (not shown).

FIG. 2 shows a Fourier transform infrared (FTIR) spectrogram of VDF oligomer thin films deposited at different substrate temperatures, namely at a substrate temperature of −80° C. and −90° C. respectively. It will be seen that while the non-polar crystalline phase II (a phase) dominates at −80° C., the polar crystalline phase I (β phase) dominates at a deposition temperature of −90° C., indicating that thin films deposited at a temperature in the interval between −80° C. and −90° C. will show an increasing fraction of the polar β phase. On the basis of spectroscopic measurements the fractions of respectively the non-polar crystalline phase II (α phase) and the polar crystalline phase I (β phase) can be evaluated as a function of temperature. This can be done by using the spectrograms. In FIG. 3 the ratio of the 1210 cm⁻¹ band to 880 cm⁻¹ band to establish the fraction of the non-polar α phase in the thin film, while the ratio of the 1273 cm⁻¹ band to the 880 cm⁻¹ band was used for establishing the fraction of the polar β phase therein. These ratios are shown in FIG. 3. Here it can be seen that while the non-polar a phase dominates at elevated temperatures, the polar β phase appears substantially at room temperature, and the fraction of the β phase continues to increase as the temperature drops. At −80° C. the β phase forms the major fraction of the VDF oligomer film and reaches a peak at about −150° C., which could be considered a minimum substrate temperature for the deposition of VDF oligomer to obtain a ferroelectric thin film.—It should be noted that the IR band at 880 cm⁻¹ is always present in all samples and its intensity is not much changed by the preparation conditions of the samples. It is thus suited as an internal reference for the evaluation of the fractions of α and β phases in oligomer and co-oligomer thin films.

On the basis of investigations carried out by the inventors it has been found that the deposition of a VDF co-oligomer, namely VDF with trifluoroethylene (VDF-TrFE), takes place along similar lines. However, with the co-oligomer VDF-TrFE the polar β phase appears as a major fraction of the VDF-TrFE co-oligomer thin film at a much higher temperature than is the case of the VDF oligomer probably around −40° C. to −50° C.

Now example embodiments of the method according to the invention shall be detailed and in that connection the importance of choosing a suitable deposition temperature form the oligomer or co-oligomer should be stressed. The deposition must take place in a temperature interval having an upper and a lower limit. The upper limit follows from the desired crystal phase (i.e. ferroelectric) and its orientation.

Not only is it important to obtain as high fraction as possible of the polar crystalline phase, but it has also been discovered that a VDF oligomer is deposited at a temperature below −80° C. the polar crystalline phase II or phase is obtained with the crystal axis of oligomers oriented parallel to the substrate. This applies to pure VDF oligomers. If the temperature increases above −80° C., the non-polar a phase starts to dominate. At higher temperatures the oligomers will be deposited with their crystal axes randomly oriented. The lower temperature limit will be dependent on the characteristics of the vacuum system prior to cooling the substrate holder for deposition. The lower temperature limit hence shall be given by the temperature where the saturation vapour pressure of water is equal to the partial pressure of water vapour in the system before cooling the substrate holder. This is related to the fact that the substrate needs to be cooled to temperatures of less than −80° C. in order to obtain the polar crystalline form I. During the cooling process some of the residual water vapour in the vacuum chamber will condense on the surface of the substrate, i.e. the wafer. For instance, with a partial pressure of water vapour of 10⁻⁶ mb and a sticking coefficient of 1, a monolayer of water molecules is formed every three seconds. FIG. 4 illustrates the vapour pressure of water as a function of temperature. It will be seen that at approximately −122° C. the vapor pressure of water is 10⁻⁶ mb, while at −140° C. the vapour pressure of water has dropped to 10⁻⁹ mb. Most ordinary high-vacuum systems have a base pressure in the range of 10⁻⁷ to 10⁻⁶ mb and a partial pressure of water of the same order, as 65-95% of the residual gas in a vacuum system is water vapour—the heavier molecules being removed preferentially to the lighter molecules when the system is evacuated. In other words, if a temperature of about −140° C. is used as a deposition temperature in a high-vacuum system, considerable amounts of water will condense on the surfaces, but a deposition temperature less than −140° C. could be acceptable in an ultra-high vacuum system with a pressure as low as 10⁻¹¹ mb. Moreover, even at temperatures just above the lower temperature limit water will condense on the surfaces, and hence a temperature as high as possible should be chosen. This is related to what happens after the deposition, when the wafer of the substrate shall be heated up to ambient temperature before removing it from the vacuum chamber. During this process the condensed water will be released from the wafer. The faster the wafer is heated, the faster the water will be released. The release of water can lead to the formation of either bubbles or cracks in the wafer, of which more below. One way to mitigate the effect of condensed water on the wafer substrate is heating the wafer slowly after the deposition of the oligomer thin films, thereby allowing the system a more extended settling time.

The oligomer or co-oligomer thin films are deposited by evaporation and to this end an evaporator system as shown in FIG. 5 and per se known in the art can be used. FIG. 5 renders a schematic cross section through a vapour deposition chamber or enclosure comprising an evaporation crucible 2 simply termed the evaporator and a substrate holder 3 supporting a substrate 8 with strip-like electrode metallizations provided on its exposed surface which here is oriented substantially parallel to the surface of the crucible coolant-transporting pipes 7 are connected with the substrate holder 3. The evaporator 2 may be of the open type or provided with a perforated lid. The enclosure 1 is connected to a vacuum pump 4 for evacuating the chamber, and moreover the chamber comprises a shutter 5 operable to control the deposition time, i.e. it closes when the desired thickness of the oligomer or co-oligomer layer has been reached, as well as means 6 for monitoring the thickness of the deposited oligomer or co-oligomer thin film. The deposition rate and the growth and thickness of the deposited thin-film can be controlled by the means for thickness monitor provided in the enclosure 1 as shown in FIG. 5.—In order to form a ferroelectric memory device the oligomer or co-oligomer films are deposited covering electrode structures provided on the surface of the substrate 8. These electrodes are usually deposited as parallel stripe-like metallizations to form a first electrode set in the ferroelectric memory device.

After the memory material in the form of oligomer or co-oligomer thin film has been deposited over the electrodes and after the final processing, the substrate with the first electrode set and the deposited ferroelectric thin film can be joined to second component part comprising an isolating back-plane with a second set of parallel stripe-like electrode similar to those in the first set, but now provided and located onto the memory thin-film layer so with the electrodes of the second set oriented perpendicular to the electrodes of the first set, whereby a memory cell capable of storing a binary digit as either of two polarization states is defined and created in the memory material between two intersecting electrodes of either set. Other possible variants of the vacuum systems of the evaporation chamber as well as other kinds of electrode structures that may be coated with ferroelectric thin films according to the method of the invention shall be discussed in more detail further below.

A first embodiment of the method according to the present invention for applying a ferroelectric thin film of vinylidene fluoride oligomer shall now be discussed.

A starting VDF oligomer having a structure as shown in FIG. 1b, i.e. of the form Y-(VDF)_{y}-Z where Y and Z are different end groups and y an integer, is selected for evaporation and deposition, preferably as powder with polydispersity larger than 1. Also preferably a starting VDF oligomer is selected with a specific length. The VDF oligomer is moreover selected with less than 100 repeat units. The substrate 8 with the electrode set to be covered by the oligomer film is mounted in the substrate holder 3 and positioned in the vacuum chamber as shown in FIG. 5. The vacuum chamber is now evacuated at a temperature which is selected as mentioned above, and in the case of the deposition of a VDF oligomer thin film is selected to lie in the range between −80° C. and −105° C. At a temperature of −80° C. the deposited VDF oligomer will be formed with a major fraction in the polar crystalline phase I or the β phase. On the other hand the temperature of the substrate holder 3 and substrate 8 shall not be lower than the temperature where the saturation vapour pressure of water in the enclosure equals the partial pressure before the cooling starts. The reason is that condensation should be avoided, in other words, if the partial pressure is 10⁻⁴ mb before the cooling starts, the minimum applicable temperature after cooling will be in the order of −100° C. However, as shown in FIG. 5, the vacuum chamber can be provided with a cold trap 9 located somewhere in the enclosure 1 and cooled to a substantially lower temperature, for instance −140° C. or below that such that vapour yet may condense and freeze thereon. In a succeeding step after a suitable cooling of the substrate which can take place by supplying a suitable coolant to the substrate holder, the VDF oligomer is evaporated with the selected evaporation deposition rate from the crucible or evaporator. It has been shown that the VDF crystal starts to sublimate already at 60° C. and the melting curve increases to a peak at 150° C. The economy of the process implies that evaporation rate should be as high as possible, which implies that the temperature of the evaporator should be above 100° C., giving deposition rate of about 2 Å/s⁻¹. Increasing the evaporator temperature, i.e. the temperature of the VDF oligomer in the crucible, to a value of approaching 150° C. will yield a substantially higher deposition rate and since the present-day development points to the likelihood of film thicknesses in the order of 150 to 100 nm thickness, it is preferred that these films can be deposited in a minute or so. As a matter of fact a deposition rate of 700 Å/min. or about 12 Å/s was successfully obtained in the actual embodiment of the method according to the invention for depositing VDF oligomer. After the desired thickness of the deposited VDF oligomer film has been reached, as measured by the thickness monitor 6 provided in the vacuum chamber, the deposition is terminated by closing for instance the shutter 5 provided between the evaporator 2 and the substrate holder 3 as shown in FIG. 5 and the substrate temperature is then fairly slowly increased to room temperature. The temperature increase can preferably take place at a rate exceeding 3K/min., indicating that the room temperature will be reached in a little more than a half hour. It should particularly be noted that the residual water vapour in the vacuum chamber is a problem as it may lead to the formation of various surface defects in deposited oligomer thin film, such as pinholes, bubbles and cracks where condensed water is released from the wafer, as mentioned above.

As already stated, while it is important that the substrate temperature is not too low during the deposition of the VDF oligomer, it must at the same time be accepted that some fraction of the deposited VDF oligomer crystallizes in the non-polar crystalline phase II or the a phase as will be the case when deposition takes place in temperature range −80° C. to −105° C. Hence in this embodiment of the method according to the invention it is a very important aspect that a final step that is carried out after the substrate has been heated to room temperature and after the deposition, that heat treatment or annealing of the deposited VDF oligomer thin film shall take place at a temperature in the range of 50° C. to 150° C. From the FTIR spectograms shown in FIG. 6 it can be seen that a VDF oligomer thin film deposited at −90° C. comprises a major fraction crystallized in the polar β phase, but still an amount of α phase non-polar crystals. Now by annealing the deposited VDF oligomer film at 100° C. the comparison of the FTIR spectograms at 100° C. with the one recorded at −90° C. shows that the contribution to the spectrum from the α phase largely disappears and hence signifies that the non-polar α phase crystals are converted to the polar β crystalline phase and improve the uniform crystallinity of the deposited VDF oligomer, resulting in a much improved oligomer thin film with additionally enhanced ferroelectric characteristics.

The advantageous ferroelectric properties of a VDF oligomer thin film deposited with the above-disclosed embodiment of the method according to the invention is corroborated by measurements of the hysteresis curve, the polarization switching behaviour and a determination of the fatigue curve. FIG. 7 shows the hysteresis curve as obtained with a 600 Å (60 nm thick) VDF oligomer film deposited between gold electrodes. The hysteresis was measured with a triangular wave with amplitude of 11 volt and at a frequency of 10 Hz. From the hysteresis curve it is seen that it has a nearly square shape although well-defined cusps, a remanent polarization of about 12.5 μC/cm², and a saturation polarization which actually is not much higher. The coercive voltage is 6 volt, and with a 60 nm thick film this indicates that the coercive field can be estimated at 100 MV/m. As well-known to persons skilled in the art now for instance the one remanent polarization state can be used to represent a stored logic zero and the other remanent polarization state can be used to represent define a stored logical one. The remanent polarization state is stable for an indefinitely long duration and a set remanent polarization state can be switched to the opposite direction by applying a switching voltage V_{S} which is higher than the coercive voltage V_{C}. As can be seen from FIG. 7, a switching voltage could for instance be about 10 volt. If it is positive, a memory cell in the positive remanent polarization state storing a logical zero will only be polarized to saturation and after turning off the switching voltage, the memory cell again reverts back to the original polarization state, thus retaining the stored logic zero. On the other hand, a memory cell in the negative remanent polarization state storing a logical one will be switched by a positive switching voltage, and the polarization state runs counterclockwise along the hysteresis curve until a positive saturation state is reached, whereafter upon turning off the switching voltage the memory cell will flip to the positive polarization state and hence now can be regarded as storing a logical zero. If this is not intended to be a rewriting process, the original logical one can only be reset by applying a similar large switching voltage −V_{S} and driving the polarization along the hysteresis curve from the positive remanent polarization state to the negative saturation value whereafter turning off the switching voltage −V_{S} will flip the memory cell back to its original state, and i.e. the negative remanent polarization state and hence the stored logical one is reset.

To confirm the results indicated by the measured hysteresis curve, a further test is carried out by performing a so-called PUND (positive up, negative down) measurement procedure using a standard pulse sequence for probing ferroelectric materials and consisting of a negative preset pulse following by a sequence of two positive pulses and two negative pulses. Such measurements have been published for very thick films, i.e. with a thickness in the order of 500 nm, but not previously for the ultrathin VDF oligomer film obtained in the above-discussed embodiment of the method according to the present invention. FIG. 8 shows the results of a PUND measurement carried out with pulses at 11 volt and of 30 μs duration. As will be seen from FIG. 8, the result confirmed the expected excellent switching behaviour, and the obtained output response curve indicates a switching time in the 100-200 ms range and a large polarization amplitude in the order of 20 μC/cm².

Finally, FIG. 9 illustrates the fatigue curve of VDF oligomer thin film with gold electrodes. As will be seen from FIG. 9, the PUND measurement confirms a switching polarization P* in the order of ±20 volts. In FIG. 9 the switching polarization P* is shown for its positive and negative value as a function of the number of switching cycles, or in other words the number of polarization reversals. Also the non-switching polarization designated \hat{P} is shown as a function of a number of switching cycles and for both the positive and negative state. In order to yield a reliable discrimination between the polarization states, it is obviously advantageous that the difference between the switching and the non-switching polarization is as large as possible up to a very high number of switching cycles. Moreover, the almost square shape of the hysteresis curve yields a non-switching polarization very close to zero. As shown in FIG. 9, all curves are nearly linear up to 10⁶ volt, and from prior art results obtained with VDF polymer or PVDF for similar cases, but where the PVDF thin film is more rapidly fatigued, it would admissible on the basis of FIG. 9 to estimate that the VDF oligomer thin film will not be significantly fatigued until well beyond 10⁸ switching cycles. This result should indeed satisfy its application as memory material in non-volatile passive addressable ferroelectric matrix memories.—As known to persons skilled in the art, fatigue is manifest as a decrease in the remanent polarization state with an increasing number of switching cycles and which would eventually lead to leave the ferroelectric memory material unfit for data storage as a safe and reliable discrimination between the set polarization remanent polarization states and hence the stored logic values can no longer be made. In other words, a completely fatigued memory material can for all practical purposes be assumed as dead. A high fatigue resistance thus is highly desirable property of any polymer or oligomer candidate memory material in ferroelectric memories. The fatigue curve obtained for the VDF oligomer hence clearly indicated that the VDF oligomer performs at least as well or better than say either PVDF or the copolymer P(VDF-TrFE) which hitherto has been the preferred ferroelectric polymer for use in memories.

To sum up, by using this embodiment of the method according to the present invention one obtains ultra-thin VDF oligomer thin films with excellent ferroelectric properties including the shape of the hysteresis curve, the temporal response of the polarization, and the fatigue behaviour. It is essential that the deposited thin film used as a memory material in sandwich between a first and second electrode sets should be defect-free and allow a trouble-free electrical probing of the polarization states and behaviour of the memory film. This is evinced by the micrograph FIGS. 10a, 10b and 10c of which FIGS. 10a and 10b show results of the depositing VDF oligomer under non-optimized conditions, as indeed actually is given in the cited prior art. It is precisely the release of water either in the deposition stage or in the step of heating the substrate to room temperature that causes defects in the form of bubbles shown in FIG. 10a or cracks shown in FIG. 10b to appear. With the above-described embodiment of the method of the invention one obtains, as will be seen from FIG. 10c, an essential completely flawless and defect-free VDF oligomer thin film. Moreover, by carrying out the deposition with the embodied method it is possible to make essentially defect-free VDF oligomer thin films over a substrate exceeding that of an eight-inch wafer. The obtained results depend on optimizing the process parameters as given by the invention and combine this to i.e. by lowering the partial pressure of water, shortening both the deposition time and the reheat to ambient temperature, thus avoiding the release and condensation of water or keeping it to a minimum such that VDF oligomer films of excellent quality and ferroelectric properties can be obtained after a suitable final annealing.

In a second embodiment of the method according to the invention a thin film of VDF co-oligomer is deposited with process steps similar to those used for depositing VDF oligomer in the above-discussed first embodiment of the method of the invention used for depositing an ultra-thin film of VDF oligomer. A VDF co-oligomer as used in the present invention has the general formula Y-(A)ₓ-(VDF)_{y}-Z, where A is the additional monomer of the VDF co-oligomer and x and y are integers, and the Y and Z are the different end groups. As the additional oligomer of the VDF co-oligomer, trifluoroethylene (TrFE) oligomer, chlorotrifluoroethylene (CTFE) oligomer, cholorodifluoroethylene (CDF) oligomer, or a tetrafluoroethylene (TFE) oligomer can be used, but these examples of preferred additional oligomers shall not be regarded as limiting as other candidate oligomers providing a polar crystalline phase might also be applicable.—Again, the VDF co-oligomer preferably is selected with less than 100 repeat units and the starting co-oligomer is selected with a specific length and preferably as a powder with a polydispersity larger than 1.

However, in the following exemplary embodiment the additional oligomer is selected as trifluoroethylene or TrFE oligomer in analogy with the widely-used ferroelectric copolymer P(VDF-TrFE). As well-known to persons skilled in the art, the P(VDF-TrFE) copolymer, although the TrFE group has a smaller dipole moment than the VDF group, has been the first choice as a ferroelectric memory material, due to the fact that it easily can be spin-coated from a solution to form a thin film with polar crystalline phase I, i.e. the β phase. The structure of the TrFE monomer is shown in FIG. 11a and a co-oligomer chain of VDF and TrFE molecules in FIG. 11b, but without specific end groups. The TrFE molecule differs only from the VDF molecule by having an extra fluorine atom in place of a hydrogen atom. As in the VDF oligomer, the backbone of the VDF-TrFE co-oligomer is formed between the neighbouring carbon atoms. The electric dipole is oriented perpendicular to the chain, i.e. the crystal c-axis as shown. It can now also easily be realized why the co-oligomer similar to the P(VDF-TrFE) co-polymer has a lower dipole moment, as the TrFE molecule compared with the VDF molecule has one hydrogen atom less and one fluorine atom more. In this second embodiment of the method of the present invention the process steps are substantially analogous to those used for depositing the VDF oligomer, although some of the process parameters will differ somewhat. In contrast with VDF oligomer the VDF-TrFE co-oligomer can be evaporated and deposited with a majority fraction in the polar β form at −40° C., and as a consequence the vacuum system must be evacuated only to a pressure of about 1 mb, as can gleaned from the curve in FIG. 4.

As disclosed in Akiyoshi Takeno & al., “Preparation and piezoelectricity of β form poly(vinylidene fluoride) thin film by vapour deposition”, Electronics and Optics, Thin Solid Films, 202, pp. 205-211 (1991), the fraction of polar VDF increases with the decreasing temperature, but it has been found by the applicant that at temperatures at about −105° C. and lower, the deposited thin films shows an increasing bumpiness which is intolerable when ultra-thin films with a thickness below 100 nm is attempted. This disadvantage has never been disclosed in the prior art research since the concern was films with a thickness in the order of 500 nm. However, the fact that VDF-TrFE co-oligomer shows a major fraction of the polar β phase already at −40° C. points to the circumstance that by decreasing the temperature to a preferred lower limit of −105° C. it will be possible to maximize the fraction of the polar β phase and yet avoid the bumpiness that otherwise would make ultra-thin films of VDF oligomer or VDF co-oligomers unfit for practical use as a ferroelectric memory material. According to the method of the invention the substrate with the VDF-TrFE co-oligomer deposited to desired thickness is heated to the room temperature at the preferred rate in less than an hour or so. Now an added advantage is that if the VDF-TrFE co-oligomer has been deposited with a maximum fraction in the polar β phase, the final step in the method of the invention can be deleted as any residual non-polar a phase will constitute a negligible fraction of the VDF-TrFE co-oligomer. However, it is nevertheless considered advisable to carry out a post-anneal treatment at a temperature exceeding 50° C. in order to optimize the crystallinity.

The ferroelectric properties of the deposited VDF-TrFE co-oligomer thin film substantiate measurement results similar to those found for the correspondingly deposited VDF oligomer. The switching behaviour of the VDF-TrFE co-oligomer mimics that of the VDF oligomer, albeit with an expected, somewhat lower polarization response.

The primary object of the present invention is to fabricate ferroelectric memory cells or ferroelectric memory devices with VDF oligomer of a VDF co-oligomer as the memory material, which by the method of the invention is provided as an ultra-thin film between the electrode structures of the ferroelectric memory cells. In analogy with memory devices as disclosed in the prior art and well-known to skilled persons, the ultra-thin VDF oligomer or co-oligomer is provided as a global layer in sandwich between first and second electrode sets. A large number of matrix-addressable ferroelectric memory arrays can be made from large wafer structures and cut to the desired dimension for a final assembly. Also as known in the art, the material of the electrode structures can be selected as for instance titanium, gold, aluminium or titanium nitride, but also be made of conducting, i.e. conjugated polymers, or combinations of these conducting materials, but by no means limited thereto. In order to minimize fatigue or undesirable reactions between the electrode material 10 and the VDF oligomer or co-oligomer memory material the wafer with the electrode structures ε₁, ε₂ can be coated as shown in FIG. 12 with an interlayer material 11 before the oligomer or co-oligomer is deposited thereon. The material of the interface layer 11 can be selected with a high dielectric constant and possible candidates can be any of the barrier materials disclosed in International published application WO03/044801. These barrier materials are selected among diamond-like nanocomposites, conducting carbides, conducting oxides, conducting borides, conducting nitrides, conducting silicides, and conducting carbon-based materials. However, the material of the interface layer 11 can also be a conducting polymer thin film as disclosed in International published application WO02/043071 and then for instance be selected among doped polypyrrole, doped polyaniline and doped polythiophenes, or derivatives of such compounds. Finally, the material of the interface layer 11 could be polyvinyl phosphonic acid (PVPA) thin-film material. In case an interface thin-film layer is used, it will be deposited onto the wafer above the first set of electrodes which then will function as word lines of the completed device, but as layers of this kind have been shown to be an important measure in order to reduce or eliminate fatigue, similar interface material can also be deposited on the opposite side of the VDF oligomer or co-oligomer memory material, forming an interface to the second set of electrodes which then will be the bit lines of the finished memory device.

In a practical realization of the fabrication process for the ferroelectric memory device the interface material can be deposited on the memory material before the second set of electrodes is deposited and patterned, something which particularly can be of advantage and lead to an enhanced protection of the memory material in case the second set of electrodes are laid down as metal films which subsequently must be patterned, for instance by ion-reactive etching, in order to provide desired electrode structures. An additional and advantageous aspect of applying an interlayer material with a high dielectric constant and low conductivity is that pinholes and other defects that may occur in the ferroelectric oligomer or co-oligomer thin films largely are eliminated and no longer pose a problem.

A practical aspect of the evaporation process that cannot be neglected is the fact that the evaporation in vacuum or high vacuum is primarily ballistic, i.e. the oligomer or co-oligomer molecules emerge from the evaporator with their kinetic energies and velocities distributed according to the laws of statistical mechanics and in every direction, and their paths will only be influenced by gravity. This may have practical implications when the electrode structures are not essentially flush with the substrate, i.e. non-planar, and hence the surface presented for deposition cannot be considered parallel to that of the evaporator. In contrast therewith, in diffusive evaporation, i.e. evaporation taking place in an ambient pressure, such as in an atmosphere, the paths of the evaporated molecules will continually change via collisions with molecules in the enclosure atmosphere and the angles by which they impinge on the electrode surfaces will be more or less equally distributed. Hence it could be considered that ballistic evaporation in certain cases will lead to an undesirable orientation of oligomer and co-oligomer molecules deposited on surface which is not parallel to that of the surface of the evaporator. For instance, if protruding or pillar-like electrode structures shall be coated with oligomer or co-oligomer thin films the substrate could be fitted with a planetary gear mechanism imparting a rotational and/or tilting movement to the substrate holder around two or more axes, whereby surfaces of protruding or three-dimensional electrode structures during the deposition on the average presents the same surface angle to the evaporator surface. Since the evaporator usually will be selected as an open-type evaporation source, optimally covered by a punctuated lid, it could in order to avoid sputtering or splashing of molten oligomer or co-oligomer be positioned in the enclosure off-axis relative to the substrate holder. Both in this case and in the ordinary position of the evaporator and in direct path to the substrate could be used by providing baffles or deflectors in the enclosure. Such means could also serve to scatter the evaporated molecules in order to obtain distributed angles of impingement on surfaces to be covered by the oligomer or co-oligomer thin film.

However, as already indicated by prior art research and as obtained with a method of the present invention, it has turned out that the oligomer or co-oligomer molecules are deposited with their electric dipoles perpendicular to the surfaces to be coated. This applies to a VDF oligomer thin film oriented as in FIG. 13a and to a VDF-TrFE co-oligomer thin film as in FIG. 13b. This means that the c-axes will be parallel to the electrode surface (or substrate) for the polar crystals.—As known in the art, an electric field could be employed in order to orient the oligomer or co-oligomer molecules, for instance by applying a potential difference between the electrode structures and an auxiliary electrode provided in the vacuum system. This auxiliary electrode could be a mesh electrode between the evaporator and the substrate as known in the art, but such measures are actually intended for use with non-cooled substrates and hence will be completely unnecessary in the context of the present invention.

An ideal arrangement of the deposited VDF oligomer or co-oligomer films is shown in FIG. 14 wherein the oligomer crystals are forming regular layers parallel to the electrode or substrate surface, i.e. with the c-axes of the crystals oriented in parallel thereto. The electrical dipoles of the oligomer molecules as well as their grain or domain boundaries will be perpendicular to the substrate. As has been found by the present inventors this ideal arrangement of the oligomer or co-oligomer crystals are obtainable with the method of the present invention which hence offers a practical way of avoiding the so-called imprint phenomenon which may be detrimental to the operation of the ferroelectric memory device. Imprint occurs when a memory cell remains in the same remanent polarization state for longer periods of time, usually for several seconds, and appears as an increase in the coercive field and hence the switching voltage needed to change the polarization state, i.e. switching the memory cell between their logic states. The imprint effect may call for special measures in order to return to normal switching conditions and can involve the application of voltage cycles at potential levels that could be detrimental to the memory cell. Imprint can be regarded as being caused by field injection of charges from the electrodes into the ferroelectric material and with trapping of the charges at the grain or domain boundaries. When the grain boundaries in the ferroelectric thin film as usual are randomly orientated, the charges will create a field in the polarization direction and thus oppose the switching field that is necessary to change the polarization state of the memory cell. The method of the present invention provides a way to control the orientation of the grain boundaries such that they are oriented perpendicular to the electrodes as apparent from FIG. 14. Any imprint field created would be perpendicular to the applied field and hence have no effect on the switching of the polarization state. In other words, the present invention offers the considerable advantage of an imprint-free ferroelectric memory cell with VDF oligomer or co-oligomer memory material deposited according to the method of the present invention.

The method according to the present invention is intended for making ferroelectric memory cells or ferroelectric memory device with the memory material in the form of a thin film of a VDF oligomer or VDF co-oligomer. The most common type in the art is ferroelectric polymer memories wherein a ferroelectric capacitor is provided by locating the ferroelectric memory material between a first electrode and a second electrode. These ferroelectric capacitors constitute the memory cells of so-called matrix-addressable ferroelectric memory device which can be of both the active and the passive type. In the active type each memory cell comprises at least one transistor and one ferroelectric capacitor with one electrode connected to a contact on e.g. field effect transistor used to switch the ferroelectric capacitor in an electrical circuit for an addressing operation. This has the advantage that in large matrix-addressable arrays only the addressed memory cells are contacting the electrodes only during the addressing operation when non-addressed memory cells are disconnected. In passive matrix-addressable ferroelectric memory arrays the memory cells are all the time in Ohmic contact with the addressing electrodes, i.e. the word line and the bit lines, and this makes unaddressed cells susceptible to so-called disturb voltages and sneak currents during addressing operations for write or read to other cells in the array.

For the sake of simplicity will the ferroelectric memory cell or ferroelectric memory device according to the invention in the following be discussed in the context of passive addressable cells or passive matrix-addressable memory devices, although of course memory cells wherein the memory material is a thin film of a ferroelectric oligomer or co-oligomer by no means shall be excluded from use in active addressable memories which thus also fall under the scope of the present invention.

FIG. 15a depicts in plan view and FIG. 15b in cross-section taken along the line A-A in FIG. 15a schematically a memory device 12 according to the present invention comprising a substrate comprising a number of parallel strip-like electrodes ε₁ provided on the substrate 8. These are then covered with a thin film of a ferroelectric VDF oligomer or co-oligomer to form a memory medium and then in the final step of course a second set of parallel strip-like electrode ε₂ are provided as a third layer in the sandwich structure, but with the parallel electrodes ε₂ oriented substantially orthogonal to the electrodes ε₁ of the first set. A memory cell e.g. 12 is now defined in the memory material 10 between a crossing bottom ε₂ and top electrode ε₁. Further discussions of a memory device of this kind and its operation are not regarded as necessary, as they will be well-known to persons skilled in the art.

When practicing the method according to the present invention the substrate 8 with bottom electrodes ε₁ is provided in the substrate holder 3 and with the electrode ε₁ usually facing the evaporator as shown in FIG. 5. The layer of the thin film of VDF oligomer or co-oligomer is then built up to the desired thickness by evaporating oligomer material from the evaporator or crucible 2 as already mentioned and shown in FIG. 5.

The method according to the present invention, being based on evaporation, allows for depositing the oligomer or co-oligomer memory material on more complex structures, which of course need not be planar. An example is for instance depicted in 15c, depicting a memory device with bridged electrodes, wherein a bottom electrode ε₁ is separated from a top electrode ε₂ by means of an insulation element 13 and the memory material 10 is then deposited such that both electrode structures ε₁, ε₂ are covered. A memory cell 12 will be formed in the memory material 10 and extends between the bottom and the top electrodes ε₁; ε₂ and along the sides of the insulating element 13. This kind of bridged electrodes relies on the stray electric field and the polarization may be significantly weaker than the one obtainable in a ferroelectric sandwich capacitor structure, but the embodiment with bridged electrodes offers the advantage that the oligomer or co-oligomer memory material 10 can be deposited over both electrodes ε₁, ε₂ and thus a metallization to form the top electrodes ε₁ carried out directly on the surface of the memory material 10 can be avoided. However, even when the memory material 10 is sandwiched between the electrode layers, the memory material can be evaporated onto the cooled substrate and the thereupon provided set of electrodes ε₁ to form the component I, while the second set of electrodes ε₂ can then be fabricated on a backplane 14 as a separate component II, as shown in FIG. 15d. After orienting the electrodes of the respective sets at substantially straight angles to each other, the two components I, II can be laminated together and the desired sandwich structure for the memory device is obtained with no need for depositing the second electrode layer directly onto the memory material 10.

Complex electrode geometries and not least three-dimensional geometries of course will be eminently suitable for use with the method of the present invention, but a oligomer or co-oligomer memory layer deposited by evaporation onto structures which no longer can be considered essentially planar or may extend in three dimensions shall make it difficult to realize a ferroelectric memory layer with the electric dipoles oriented perpendicularly to the substrate or an electrode surface. However, recently in a co-pending NO patent application assigned to the present applicant there has been disclosed non-planar, i.e. three-dimensional electrode structures and particularly pillar-like electrodes where the memory material is deposited between the electrodes such that memory cells are formed for instance between opposing surfaces of a pair of pillar-like electrodes. The implication is that an orthogonal memory array with m columns and n rows now can be formed with a theoretical number of memory cells equal to 2 mn−(m+n). If the array is square with m columns and m rows, this expression reduces to 2 m²-2 m. Although this is an ideal number which may be difficult to achieve due to contacting problems, such electrodes offer interesting topologies, not least for volumetric ferroelectric memories with high storage density. In the context of the present invention this means that the side surfaces of the pillar-like electrodes, i.e. structures protruding from a substrate, should preferably be covered with a VDF oligomer or co-oligomer memory film oriented with the crystal axis parallel to the surfaces. FIG. 16a shows a plan view of a substrate 8 provided with a square m×m array of pillar-like electrodes ε that for instance can be made with conventional methods used in integrated circuit fabrication. FIG. 16b shows a cross section through the memory array taken along the line A-A in FIG. 16a and the pillar-like electrodes ε or electrode posts which have a square footprint in the substrate plane with their vertical side surfaces parallel to the vertical surfaces of neighbour electrodes. The substrate 8 with the pillar-like electrodes ε are mounted in the substrate holder 3 in the vacuum chamber and the VDF oligomer or co-oligomer is evaporated to form a layer over all surfaces. Hence the crystal axes of the deposited oligomer chains will be parallel to the side surfaces of the electrodes ε and similarly to the substrate 8 between them, as all structures to be covered of course are cooled to the preferred temperature used in the method of the invention, for instance to about −80° C. to −105° C. in case of depositing a VDF oligomer.

With reference to FIG. 17a-17e the process steps in an embodiment of the method according to the invention for realizing pillar-like electrode structures with memory cells defined between opposing side surfaces of neighbouring electrodes of this kind shall now be discussed in some detail. Electrodes in the form of pillar-like or post-like structures are provided on a substrate 8 by means of procedures well-known in the fabrication of semiconductor devices and integrated circuits. After patterning, the electrodes E appear with a large aspect ratio and hence separation or distance between the electrodes ε can be a fraction of the chosen height or depth thereof, as these parameters will not be limited by the design rule of the applied patterning process. The substrate 8 with the protruding electrode structures are placed in the enclosure and VDF oligomer or co-oligomer is evaporated to form a growing deposit 10 on the electrodes ε₁ as well as the exposed surface of the substrate 8. The build-up of this thin-film layer 10 is not yet complete as shown in FIG. 18a, where moreover the direction or the orientation of the electrical dipoles are indicated in the layer 10. This orientation will of course depend on the orientation of the underlying cooled surface. In FIG. 17b the substrate 8 with the electrodes ε₁ has been completely covered by a thin film 10 of VDF oligomer or co-oligomer which fills the volume between the electrodes ε completely. In other words, the whole structure is now covered by a thin film layer 10 of VDF oligomer or co-oligomer extending to some distance h₁ above the electrodes ε₂. As will be seen, the electric dipoles are orthogonal to the side surfaces of the electrodes ε in the mid section of the latter, while this orientation is disturbed in the vicinity of the substrate surface and in the portion of h₁ of the thin-film layer, due to the orientation of the underlying or adjacent cooled surfaces. The portion h₁ is now removed, for instance by chemical milling, and the resulting surface if planarized, whereafter it is covered with a substrate or backplane 14a comprising not shown appropriate contacting and connecting means for the electrodes ε as shown in FIG. 17c. In a subsequent processing step the substrate 8 is stripped off and the portion h₂ of the electrodes and the deposited VDF oligomer or co-oligomer is completely removed, for instance by chemical milling. The resulting planar surface is planarized and provided with a substrate or backplane 8a comprising appropriate means for contacting the electrodes. The resulting device as it appears in cross-section in FIG. 17d shows a section through a row of pillar-like electrode structures ε. Memory cells 12 are formed in the memory material 10 filling the volumes between the electrodes ε and with electrical dipoles perpendicular to the electrode surfaces as indicated. The substrates or backplanes 8a, 14a, must as mentioned, comprise the required contacting and addressing means for the electrodes for performing write and read to the memory cells. The latter are as shown in FIG. 17e and formed in volumes of memory material 10 between opposing surfaces of electrode pairs and with the possible combinations indicated by the arrows. The memory cells are schematically rendered arranged in a square array of 3×3 pillar-like electrodes. By using the above formula it is easily seen that the theoretical number of possible individually addressable memory cells is 2×3²−(2×3)=12. Hence the maximum number of memory cells that in this manner can be realized between opposing surface of electrode pairs approaches twice the number of electrodes as the size of the array, i.e. the product m×n increases, where m is the number of columns and n the number of rows in the array.

It should be noted that very complex geometries, generally any three-dimensional structure provided on a substrate, can be handled with the method of the present invention and covered with a layer of a VDF oligomer or co-oligomer thin film. However, it will not always be possible to provide memory layers with crystal axes everywhere parallel to any surface, but certain post-processing operations carried out in the fabrication of memories could allow for the creation of ferroelectric memory cells with VDF oligomer or co-oligomer thin films having the proper orientation to the electrode surfaces, which no longer need to be planar with substrates and backplanes comprising the required contacting and addressing means and from which the electrodes protrude. However, such post-processing operations are considered to lie outside the scope of the present application, although appropriate measures and solutions can be considered known to persons skilled in the art.

1. A method for forming ferroelectric thin films of vinylidene fluoride (VDF) oligomer or vinylidene fluoride (VDF) co-oligomer, wherein the VDF oligomer or VDF co-oligomer with another oligomer is deposited and forms a thin film on a substrate by means of evaporation, and wherein the evaporation takes place in a sealed enclosure containing the substrate and an evaporation source, characterized by steps for
a) evacuating the sealed enclosure to a pressure below 1 mbar,
b) cooling the substrate to a temperature in the range where a major fraction of the oligomer or co-oligomer crystallizes in a polar crystalline phase and oriented parallel to the substrate, but not below a temperature at which the saturation vapour pressure of water in the enclosure becomes equal to the partial pressure of water vapour before the cooling starts, and in any case not below −150° C.,
c) evaporating the oligomer or co-oligomer onto the substrate to form a thin film with a predetermined thickness,
d) increasing the temperature of the substrate to room temperature after the deposited oligomer or co-oligomer thin film has reached the predetermined thickness, and
e) heating the deposited thin film of oligomer or co-oligomer to a temperature in the range 50° C. to 150° C. in order to anneal the deposited thin film, whereby a residual non-polar crystalline phase is converted to a polar crystalline phase.

2. A method according to claim 1,
characterized by selecting the VDF oligomer or VDF co-oligomer with less than 100 repeat units.

3. A method according to claim 1,
characterized by selecting a starting VDF oligomer or VDF co-oligomer with a specific length.

4. A method according to claim 1,
characterized by selecting a starting VDF oligomer or VDF co-oligomer as a powder with a polydispersity larger than 1.

5. A method according to claim 1,
characterized by selecting the VDF co-oligomer or any oligomer of the form Y-(A)ₓ-(VDF)_{y}-Z, where Y and Z are different end groups, A a monomer different from VDF, and x and y integers.

6. A method according to claim 1,
characterized by selecting an oligomer of the VDF co-oligomer as trifluoroethylene(TrFE) oligomer, chlorotrifluoroethylene (CTFE) oligomer, chlorodifluoroethylene (CDFE) oligomer, or tetrafluoroethylene (TFE) oligomer.

7. A method according to claim 5,
characterized by selecting at least one of the end groups of the oligomer or co-oligomer with a functionality selected as CCl₃, OH, SH, COOH, COH or POOH.

8. A method according to claim 1,
characterized by evacuating the sealed enclosure in step a) to a pressure in the range 10⁻⁴ to 10⁻⁶ mbar.

9. A method according to claim 1,
characterized by cooling the substrate in step b) to a temperature in the range −40° C. to −105° C.

10. A method according to claim 9, wherein the ferroelectric thin film is a VDF oligomer,
characterized by cooling the substrate to a temperature in the range −80° C. to −105° C.

11. A method according to claim 9, wherein the ferroelectric thin film is a VDF co-oligomer,
characterized by cooling the substrate to a temperature in the range −40° C. to −105° C.

12. A method according to claim 1,
characterized by the polar crystalline phase of VDF oligomer or VDF co-oligomer being the β crystalline phase.

13. A method according to claim 1,
characterized by transferring the cooled substrate to a holder cooled to the temperature of the substrate and provided in the enclosure just prior to step c).

14. A method according to claim 1,
characterized by providing a cold surface in the enclosure and cooling the former to temperature lower than that of the cooled substrate.

15. A method according to claim 14,
characterized by cooling the cold surface to a temperature below −140° C.

16. A method according to claim 1,
characterized by using an evaporation rate of 2 to 2000 Å/min.

17. A method according to claim 1,
characterized by selecting the predetermined thickness of the VDF oligomer or VDF co-oligomer thin film in the range 50 Å to 3000 Å.

18. A method according to claim 1,
characterized by increasing the temperature in step d) at a rate exceeding 3 K/min.

19. A method according to claim 1,
characterized by using an open-type evaporation source, preferably covered by perforated lid.

20. A method according to claim 1,
characterized by positioning the evaporation source in the enclosures so as to avoid sputtering or splashing of molten VDF oligomer or VDF co-oligomer onto the substrate.

21. A method according to claim 20,
characterized by positioning the evaporation source relative to the substrate so as to obtain an indirect path therebetween.

22. The use of the method according to claim 1 in the fabrication of ferroelectric memory cells or ferroelectric memory devices, wherein the ferroelectric material is provided in the form of a thin film of VDF oligomer or a VDF co-oligomer located between one or more of first and second electrode structures.

23. The use of the method according to claim 22,
wherein the material of the electrode structures is selected as titanium, gold, aluminum, or titanium nitride, or conducting polymer, or combinations thereof.

24. The use of the method according to claim 22,
wherein an interface layer is provided between at least one of said first and second electrode structures and the thin film of VDF oligomer or VDF co-oligomer.

25. The use of the method according to claim 24,
wherein the material of interface layer is selected with a high dielectric constant.

26. The use of the method according to claim 24,
wherein the material of the interface layer is selected as a conducting polymer thin film or a polyvinyl phosphonic acid (PVPA) thin-film material.

27. A ferroelectric memory cell or ferroelectric memory device,
comprising a ferroelectric memory material (10) in the form of a thin film of VDF oligomer or VDF co-oligomer is provided between at least one of first and second electrode structures (ε₁; ε₂), characterized in that the thin film of VDF oligomer or VDF co-oligomer provided wholly in its polar crystalline phase without defects and with a parallel orientation of to the surface thereof on at least one of the electrode structures (ε₁; ε₂), or between the first and second electrode structures (ε₁; ε₂) of said at least one of first and second electrode structure.

28. A ferroelectric memory device according to claim 27,
characterized in that the first and second electrode structures are provided respectively as sets of parallel stripe electrode on respective non-conducting substrates or backplanes (8), said non-conducting substrates with the provided electrode structures (ε₁; ε₂) being positioned such that the electrodes of said first and second sets are oriented mutually perpendicular and with the ferroelectric memory material (10) in the form of the thin film of VDF oligomer or VDF co-oligomer provided therebetween, whereby memory cells (12) are formed in the ferroelectric memory materials between the crossing electrodes (ε₁; ε₂).

29. A ferroelectric memory device according to claim 27,
characterized in that the first and second electrode structures (ε) are provided on an insulating substrate or backplane (8) and protruding outwards therefrom, and that the ferroelectric memory material (10) in the form of the thin films of VDF oligomer or VDF co-oligomer is provided in the recesses formed between adjacent protruding first and second electrode structures, whereby memory cells are formed therebetween.

30. A ferroelectric memory device according to claim 27,
characterized in that the electrode structures (ε) are provided on an insulating substrate or backplane (8) and protruding outwards therefrom, and that ferroelectric material (10) in the form of the thin films of VDF oligomer or VDF co-oligomer is provided as conformal coatings on one or more surfaces of said electrode structures, whereby memory cells (12) are formed between surfaces of first and second electrode structures.
